(19) United States
(12) Patent Application Publication
(10) Pub. No.: US 2025/0319570 A1
(43) Pub. Date: Oct. 16, 2025

(54) CONTACT CLEANING UNITS IN CMP POLISHER

(71) Applicant: Applied Materials, Inc., Santa Clara, CA (US)

(72) Inventors: Haosheng WU, Fremont, CA (US); Shou-Sung CHANG, Mountain View, CA (US); Sameer A. DESHPANDE, Milpitas, CA (US); Asheesh JAIN, Livermore, CA (US); Justin H. WONG, Pleasanton, CA (US); Sidney P. HUEY, Fremont, CA (US); Derek R. WITTY, Fremont, CA (US); Jianshe TANG, San Jose, CA (US); Chih Hung CHEN, Sunnyvale, CA (US); Jeonghoon OH, Saratoga, CA (US); Chad POLLARD, San Jose, CA (US); Hui CHEN, Tempe, AZ (US)

(21) Appl. No.: 18/632,450

(22) Filed: Apr. 11, 2024

(51) Int. Cl. B24B 37/34; H01L 21/02

(52) U.S. Cl. CPC B24B 37/345; H01L 21/02057

(57) ABSTRACT

Embodiments of the disclosure provided herein include systems and methods for reducing substrate transfer and air time in chemical mechanical polishing systems. The system includes one or more polishing stations disposed within a polishing module, a contact cleaning unit disposed adjacent to the one or more polishing stations, and a controller. The controller is configured to transfer the substrate to a first polishing station of the one or more polishing stations, transfer the substrate to the contact cleaning unit from the first polishing station, and clean the substrate using a contact cleaning method. A method includes placing a substrate on a first non-contact cleaning unit cleaning the substrate using a first non-contact cleaning method, transferring the substrate to a first polishing station, transferring the substrate to a contact cleaning unit from the first polishing station, and cleaning the substrate using a contact cleaning method.

### BACKGROUND

### Field

Embodiments of the present invention generally relate to electronic device manufacturing, and in particular, to chemical mechanical polishing (CMP) systems and methods used in a semiconductor device manufacturing processes.

### Description of the Related Art

The transfer and air time of a substrate within a chemical mechanical polishing (CMP) system can affect the quality of the substrate. Transfer time, denoting the duration required to relocate the substrate from one station to another in the CMP system, encompasses movements such as transferring the substrate from a carrier to a polishing pad, from the polishing pad to a rinse station, and from the rinse station to a subsequent station in the process. Concurrently, air time refers to the interval during which the substrate is exposed to air between stations in the CMP system, encompassing both travel time between stations and the duration the substrate awaits processing at the subsequent station.

Both transfer time and air time contribute to potential substrate contamination. Exposure to air provides an opportunity for the substrate to accumulate dust particles and other contaminants, subsequently transferring them to the polishing pad and resulting in scratches or other defects on the substrate surface. Further, these temporal factors can impact the uniformity of the CMP process. In instances where the substrate is not quickly transferred between stations, slurry may dry on the substrate surface, leading to uneven material removal and compromising substrate uniformity.

Additionally, extended air exposure can cause surface oxidation, contributing to increased subsurface damage that weakens the substrate, making it more prone to breakage.

Accordingly, there is a need for an improved method and apparatus that reduces substrate transfer and air time in CMP systems.

### SUMMARY

Embodiments of the present invention generally relate to electronic device manufacturing, and in particular, to chemical mechanical polishing (CMP) systems and methods used in a semiconductor device manufacturing processes. More particularly, embodiments herein provide for processes and methods for reducing substrate transfer and air time in CMP systems.

In an embodiment, a system for polishing a substrate is provided. The system includes one or more polishing stations disposed within a polishing module, a contact cleaning unit disposed adjacent to the one or more polishing stations, and a controller configured to transfer the substrate to a first polishing station of the one or more polishing stations, transfer the substrate to the contact cleaning unit from the first polishing station, and clean the substrate using a contact cleaning method.

In another embodiment, a system for polishing a substrate is provided. The system includes one or more polishing stations disposed within a polishing module in a circular arrangement, a contact cleaning unit disposed adjacent to the one or more polishing stations, and a controller configured to transfer the substrate to a first polishing station of the one or more polishing stations, transfer the substrate to the contact cleaning unit from the first polishing station, and clean the substrate using a contact cleaning method.

In yet another embodiment, a method for polishing a substrate is provided. The method includes placing a substrate on a first non-contact cleaning unit cleaning the substrate using a first non-contact cleaning method, transferring the substrate to a first polishing station, transferring the substrate to a contact cleaning unit from the first polishing station, and cleaning the substrate using a contact cleaning method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1A is a schematic top view of a chemical mechanical polishing (CMP) system, according to certain embodiments.

FIG. 1B is a schematic top view of a CMP system, according to certain embodiments.

FIG. 2A is an isometric view of a contact cleaning unit which may be utilized in the CMP system of FIG. 1A or 1B, according to certain embodiments.

FIG. 2B is a top view of a brush cleaner in FIG. 2A, according to certain embodiments.

FIG. 2C is an isometric view of one or more embodiments of a scrubbing device disposed within the brush cleaner of FIG. 2B, according to certain embodiments.

FIG. 3 illustrates a flow diagram of a method of polishing a substrate which may be performed by a controller of a CMP system, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein generally relate to chemical mechanical polishing (CMP) systems, and in particular, to cleaning systems used with CMP systems and methods related thereto.

The transfer and air time of a substrate in a chemical mechanical polishing (CMP) system significantly affect the quality of the substrate. Transfer time involves moving the substrate between different stations in the CMP system, while air time refers to the duration the substrate is exposed to air during these movements. Both transfer time and air time contribute to potential substrate contamination, as extended exposure to air can lead to the accumulation of dust particles and contaminants on the substrate surface, causing defects. These factors also impact the uniformity of the CMP process, with slow transfers potentially resulting in slurry drying on the substrate surface, leading to uneven material removal and reduced substrate uniformity. Prolonged transfer and air times can result in surface oxidation and heightened subsurface damage, ultimately weakening the substrate and increasing the risk of breakage.

The present disclosure provides for improved systems and methods that incorporate contact clean modules within a polishing module rather than in a post-CMP cleaning module. These contact clean modules reduce substrate transfer time and defectivity between polishing processes within the CMP system.

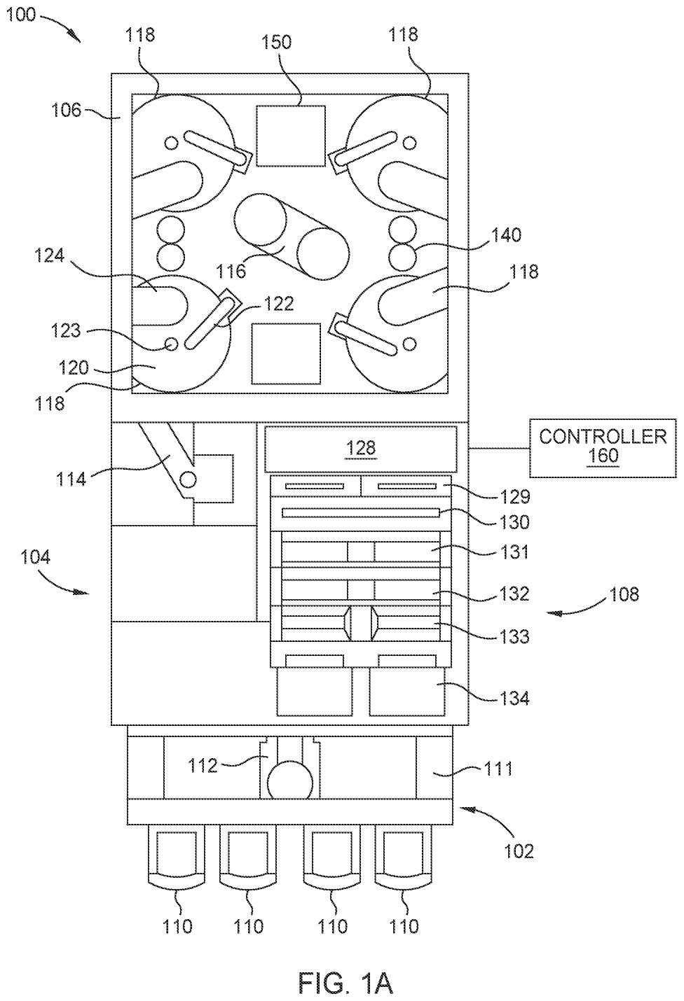

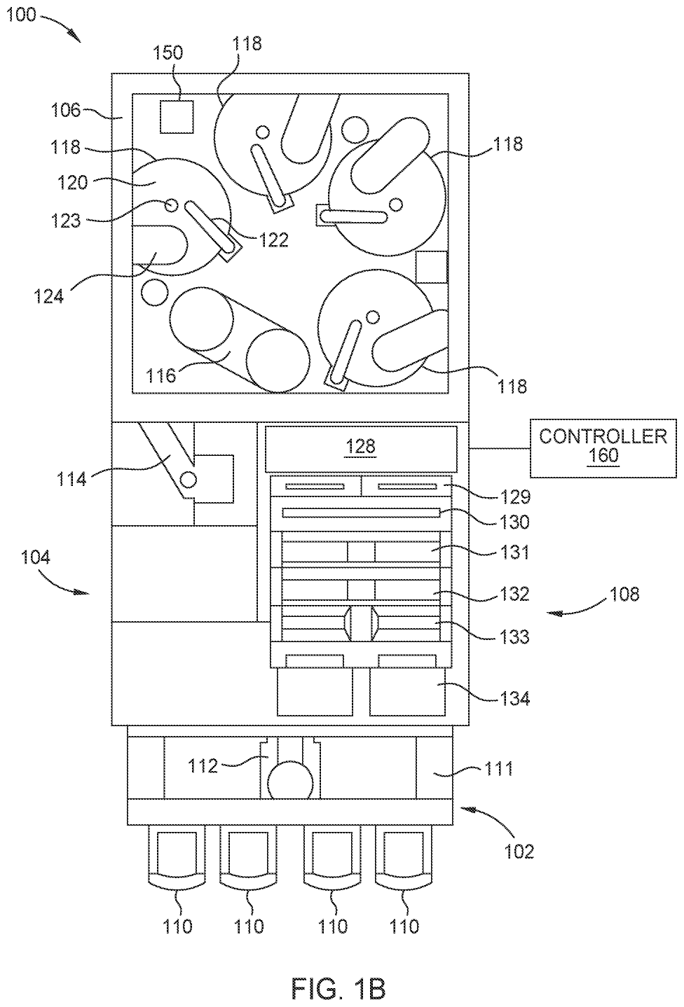

FIG. 1A illustrates a schematic top view of a chemical mechanical polishing (CMP) system 100A. The CMP system 100A generally includes a factory interface module 102, an input module 104, a polishing module 106, and a cleaning module 108. These four major components are generally disposed within the CMP system 100A.

The factory interface module 102 includes a support to hold a plurality of cassettes 110, a housing 111 that encloses a chamber, and one or more interface robots 112. The interface robot 112 generally provides the range of motion required to transfer substrates between the cassettes 110 and one or more of the other modules of the CMP system 100A.

Unprocessed substrates are generally transferred from the cassettes 110 to the input module 104 by the interface robot 112. The input module 104 generally facilitates transfer of a substrate between the interface robot 112 and a transfer robot 114. The transfer robot 114 transfers the substrate between the input module 104 and the polishing module 106.

The polishing module 106 generally includes a transfer station 116, one or more polishing stations 118, one or more non-contact cleaning units 140, and one or more contact cleaning units 150. The transfer station 116 is disposed within the polishing module 106 and is configured to accept the substrate from the transfer robot 114. The transfer station 116 transfers the substrate to at least one carrier head 124 of a polishing station 118 that retains the substrate during polishing.

The polishing stations 118 each includes a rotatable disk-shaped platen on which a polishing pad 120 is situated. The platen is operable to rotate about an axis. The polishing pad 120 can be a two-layer polishing pad with an outer polishing layer and a softer backing layer. The polishing stations 118 each further includes a dispensing arm 122, to dispense a polishing liquid, e.g., an abrasive slurry, onto the polishing pad 120. In the abrasive slurry, the abrasive particles can be silicon oxide, but some polishing processes use cerium oxide abrasive particles. Each polishing station 118 can also include a conditioner head 123 to maintain the polishing pad 120 at a consistent surface roughness.

The polishing stations 118 each includes at least one carrier head 124. The at least one carrier head 124 is operable to hold a substrate against the polishing pad 120 during a polishing operation. Following the polishing operation performed on a substrate, the at least one carrier head 124 transfers the substrate back to the transfer station 116.

The transfer robot 114 then removes the substrate from the polishing module 106 through an opening connecting the polishing module 106 with the remainder of the CMP system 100A. The transfer robot 114 removes the substrate in a horizontal orientation from the polishing module 106 and transfers the substrate to the cleaning module 108.

The non-contact cleaning unit 140 may employ methods like megasonic cleaning or spray cleaning to eliminate particles and contaminants from the substrate surface. For example, the non-contact cleaning unit 140 may include megasonic cleaning, which utilizes high-frequency sound waves to create cavitation bubbles in the cleaning solution. The implosion of these bubbles generates shock waves that dislodge particles and contaminants from the substrate surface. Alternatively, the non-contact cleaning unit 140 may include spray cleaning, where high-pressure jets of cleaning solution are used to dislodge particles and contaminants. The non-contact cleaning unit 140 may be a single-arm spray cleaning module, employing a single spray arm moving back and forth across the substrate or a dual-arm spray cleaning module with two spray arms moving in opposite directions. Further, the non-contact cleaning unit 140 may be a rotating spray cleaning module that features a rotating spray head above the substrate, spraying cleaning solution from all angles. Additionally, the non-contact cleaning unit 140 may be an inline spray cleaning module integrated into the CMP process line, transporting the substrate on a conveyor belt and spraying it from multiple angles. Conversely, an off-line spray cleaning module operates independently, cleaning substrates outside the CMP process line, which may be loaded manually or with the transfer robot 114.

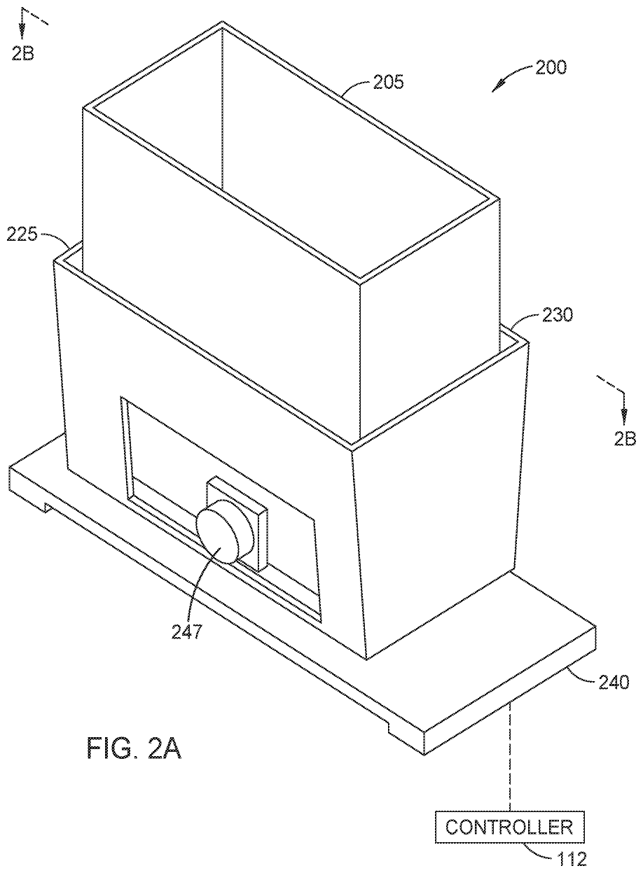

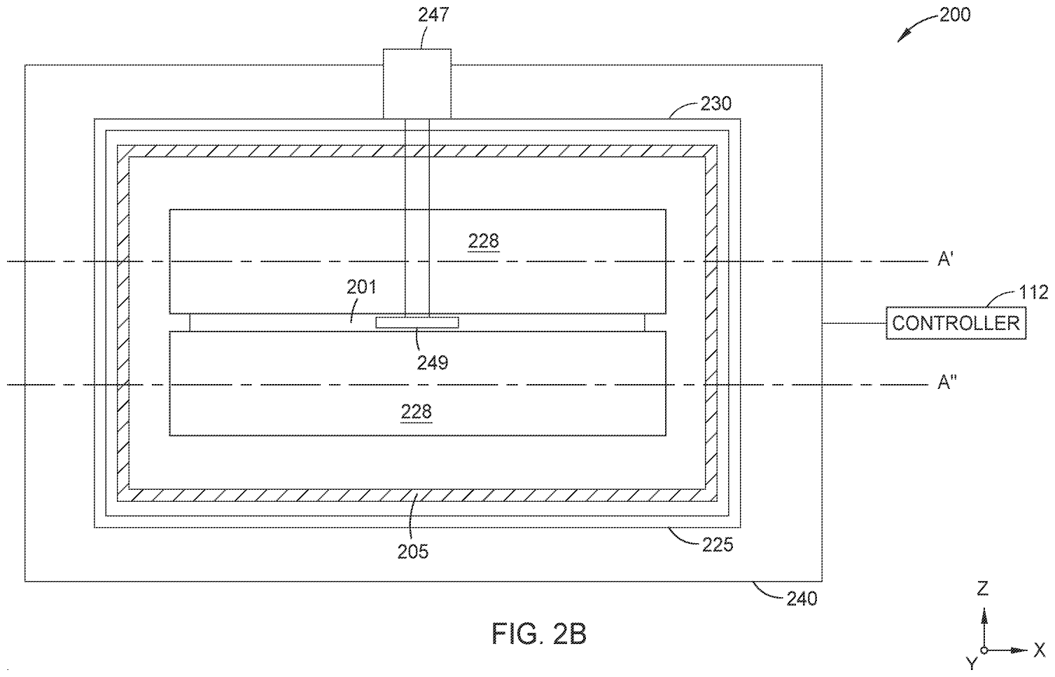

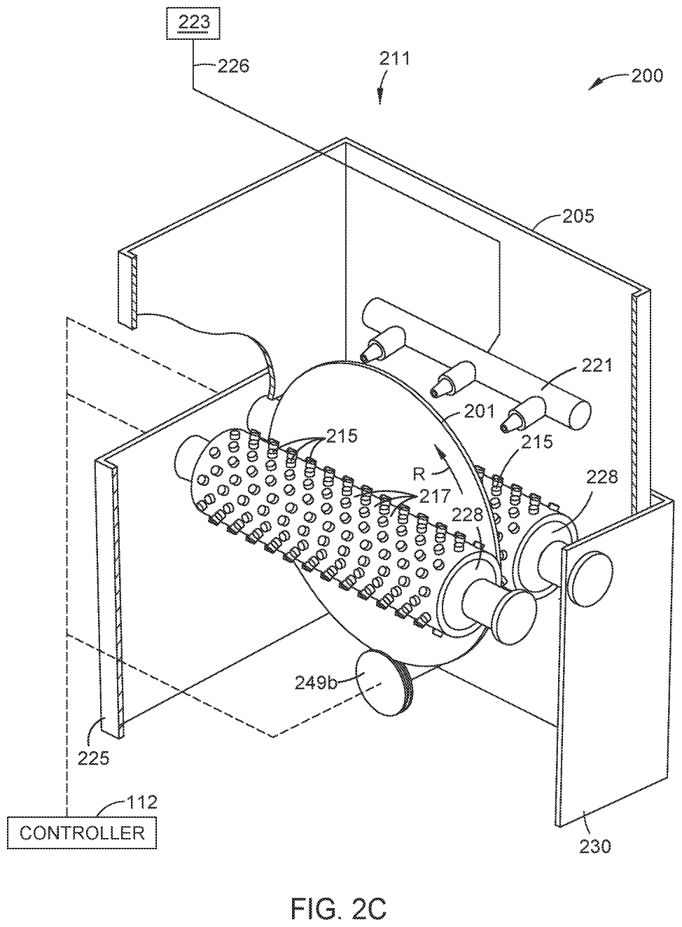

The contact cleaning unit 150, described further below regarding FIGS. 2A-2C, directly contacts the substrate and may be a brush scrubbing module using a rotating brush to scrub the substrate surface. The brush moves back and forth across the substrate, applying cleaning solution during the scrubbing process. The rotating brush uses friction between the brush bristles and the substrate surface, as well as centrifugal force generated by the rotating brush to dislodge particles and contaminants from the substrate surface. The cleaning solution concurrently dissolves and weakens the bonds between particles and the substrate surface. Following dislodgment of contaminants from the substrate surface, the cleaning solution, flowing through the brush bristles, flushes the contaminants from the substrate surface.

The non-contact cleaning units 140 and the contact cleaning units 150 are disposed between the polishing stations 118 such that the contact cleaning units 150 are in the pass-through between adjacent polishing stations 118. The non-contact cleaning units 140 are adjacent to the at least one carrier head 124 of each of the polishing stations 118, such that the substrate undergoes a non-contact cleaning immediately before being polished in the 118. Having the contact cleaning units 150 in the pass-through between polishing stations 118 minimizes polishing-station-to-brush-clean transfer time, reducing defects in the substrate, and reducing the need for additional contact cleaning units in the cleaning module 108 resulting in a reduced overall footprint of the entire tool. Alternatively, the CMP system 100A may only have the contact cleaning units 150.

The cleaning module 108 generally includes one or more cleaning devices that can operate independently or in concert. For example, the cleaning module 108 can include, from top to bottom in FIG. 1, a sulfuric peroxide mixture (SPM) module 128, an input module 129, one or more brush or buffing pad cleaners 131, 132, a megasonic cleaner 133, and a drying module 134. Other possible cleaning devices include chemical spin cleaners and jet spray cleaners (not shown). A transport system, e.g., an overhead conveyor 130 that supports robot arms, can walk or run the substrate from cleaning device to cleaning device. Additionally, overhead transfer robots can be used for this same transport of substrates. Briefly, the one or more brush or buffing pad cleaners 131, 132 are devices in which the substrate can be placed and the surfaces of the substrate are contacted with rotating brushes or spinning buffing pads to remove any remaining particulates. The substrate is then transferred to the megasonic cleaner 133 in which high frequency vibrations produce controlled cavitation in a cleaning liquid to clean the substrate. Alternatively, the megasonic cleaner 133 can be positioned before the brush or buffing pad cleaners 131, 132. A final rinse can be performed in a rinsing module before being transferred to the drying module 134.

The CMP system 100A includes a controller 160, which generally includes one or more processors, memory, and support circuits. The one or more processors may include a central processing unit (CPU) and may be one of any form of a general purpose processor that can be used in an industrial setting. The memory, or non-transitory computer-readable medium, is accessible by the one or more processors and may be one or more of memory such as random access memory (RAM), read only memory (ROM), floppy disk, hard disk, or any other form of digital storage, local or remote. The support circuits are coupled to the one or more processors and may include cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors, the one or more processors controls the CMP system 100A to perform processes in accordance with the various methods disclosed herein.

FIG. 1B illustrates a schematic top view of a CMP system 100B and is configured similar to CMP system 100A, except as otherwise described. As shown in FIG. 1B, the polishing stations 118 may be placed in a circular arrangement. In such a configuration, the non-contact cleaning unit 140 and the contact cleaning units 150 are disposed between the polishing stations 118 such that the contact cleaning units 150 is in the pass-through between adjacent polishing stations 118. The non-contact cleaning units 140 are adjacent to the at least one carrier head 124 of each of the polishing stations 118, such that the substrate undergoes a non-contact cleaning immediately before being polished in the 118. Having the contact cleaning units 150 in the pass-through between polishing stations 118 minimizes polishing-station-to-brush-clean transfer time, reducing defects in the substrate, and reduces the need for additional contact cleaning units in the cleaning module 108 resulting in a reduced overall footprint of the entire tool. Alternatively, the CMP system 100B may only have the contact cleaning units 150.

FIG. 2A is an isometric view of a contact cleaning unit 150, e.g., brush cleaner 200, which may be utilized in the CMP system 100 as described above. A lid portion of the brush cleaner 200, which includes a door, has been removed from FIGS. 2A and 2B for ease of discussion. The brush cleaner 200 shown in FIG. 2A can be a scrubber type brush box-type horizontal cleaner. The example brush cleaner 200 includes a tank 205 that is supported by a first support 225 and a second support 230. The brush cleaner 200 includes a cylindrical roller 228 coupled to an actuator (not shown) located inside the tank 205 (shown in FIG. 2B).

In operation, the first and second supports 225, 230 may be moved simultaneously relative to a base 240. Such movement may cause the first and second cylindrical rollers 228 to close against the substrate 201 as shown in FIG. 2C, or to cause the first and second cylindrical rollers 228 to be spaced apart to allow insertion and/or removal of the substrate 201 from the brush cleaner 200.

FIG. 2B is a top view of the brush cleaner 200 in FIG. 2A showing the cylindrical rollers 228 in a processing position where the cylindrical rollers 228 are closed or pressed against major surfaces of the substrate 201. The brush cleaner 200 also includes a rotational device 247. The rotational device 247 includes a roller 249, which is disposed at the end of an output shaft of the rotational device 247 and is configured to support and/or engage the substrate 201 and facilitate rotation of the substrate 201 about an axis that is perpendicular to the horizontal plane (i.e., X-Y plane).

During processing in the brush cleaner 200, the cylindrical rollers 228 are brought into contact with a substrate while they are rotated, and while the substrate 201 is rotated by use of the supporting rollers 249 that are coupled to the output shafts of the rotational device 247. A second processing fluid, such as deionized (DI) water and/or one or more second substrate cleaning fluids (e.g., acid or base containing aqueous solution), is applied to the surface of the substrate 201 from a second fluid source while the substrate 201 and cylindrical rollers 228 are rotated by the various actuators and motors.

FIG. 2C is an isometric view of one or more embodiments of a scrubbing device 211 disposed within the brush cleaner 200. The scrubbing device 211 shown in FIG. 2C is depicted with a substrate 201 loaded therein, such that the scrubbing device 211 is in a loaded state. The scrubbing device 211 includes a pair of cylindrical rollers 228. Each brush includes a set of multiple raised nodules 215 across the surface of the brush, and a set of multiple valleys 217 located among the nodules 215. The pair of cylindrical rollers 228 are supported by a pivotal mounting adapted to move the cylindrical rollers 228 into and out of contact with the substrate 201 (e.g., a semiconductor wafer) supported by a substrate support (which may also be referred to as a wafer support), thus allowing the cylindrical rollers 228 to move between closed and open positions so as to allow a substrate 201 to be extracted from and inserted therebetween as described below.

The scrubbing device 211 also includes a substrate support adapted to support and further adapted to rotate a substrate 201. In one aspect, the substrate support may include a plurality of rollers 249 (one shown) each having a groove adapted to support the substrate 201 vertically.

The scrubbing device 211 may further include sprayers 221 coupled to a source 223 of cleaning fluid via a supply pipe 226. The sprayers 221 are configured to dispense a high-pressure liquid spray onto the substrate surfaces, aiding in the removal of particles, contaminants, and residues. The sprayers 221 can incorporate various configurations, such as a fluid jet, spray bar with nozzles, shower-style spray manifold, or cryogenic aerosol jet.

In various embodiments of the present disclosure, the cleaning fluid utilized in the brush cleaner may include, but is not limited to deionized (DI) water, diluted citric acid, diluted Quaternary ammonium compound (a mixture of organic solvents, such as glycol ether, tetramethyl ammonium hydroxide, and other additives), diluted ammonium hydroxide (NH₄OH), diluted hydrogen peroxide (H₂O₂), NH₄OH and H₂O₂ mixture (SC1), diluted hydrofluoric acid, sulfuric acid (H₂SO₄) and hydrogen peroxide (H₂O₂) mixture (SPM), Electra clean, or any other liquid solution used for substrate cleaning.

In one or more embodiments, the sprayers 221 may be positioned to spray a cleaning fluid at the surfaces of the substrate 201 or at the one or more scrubber brushes during a scrubbing process. In one or more embodiments, substrate cleaning fluid and/or brush cleaning fluid may be supplied from an internal region of the scrubber brushes (e.g., cylindrical rollers 228) themselves. Fluids provided to the interior of the scrubber brushes passes through pores to clean the surface of the substrate or remove debris found on the surface of the scrubber brushes.

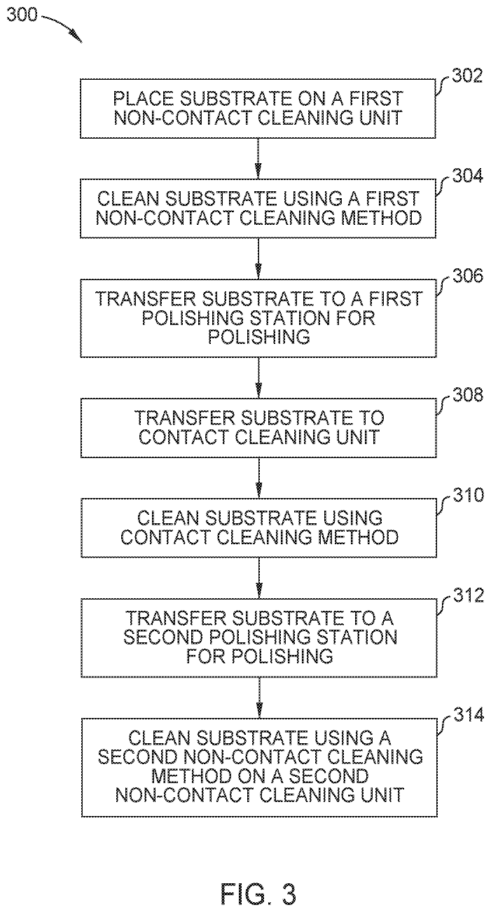

FIG. 3 illustrates a flow diagram of a method 300 of polishing a substrate, e.g., substrate 201, which may be performed by a controller of a CMP system, e.g., controller 160 of CMP system 100A. In operation 302, the substrate 201 is placed on the non-contact cleaning unit 140 by a robot arm (not shown). The non-contact cleaning unit 140 then cleans the substrate 201 in operation 304 using a non-contact cleaning method, such as megasonic cleaning or spray cleaning. For example, the substrate 201 may undergo spray cleaning where the 140 uses high-pressure jets of cleaning solution directed toward the substrate 201 to dislodge particles and contaminants.

Once cleaned, the substrate 201 is transferred, e.g., by the transfer station 116, to one of the at least one carrier head 124 of a first polishing station of the polishing stations 118 for polishing in operation 306.

In operation 308, the substrate 201 is transferred from the first polishing station to a contact cleaning unit 150. The contact cleaning unit 150 then cleans the substrate 201 in operation 310 using a contact cleaning method, such as brush scrubbing, to clean the substrate 201. For example, the contact cleaning unit 150 may be a horizontal brush cleaner, e.g., brush cleaner 200, which is adapted to rotate cylindrical rollers 228 that are pressed against major surfaces of the substrate 201. The cylindrical rollers 228 may the substrate as a processing fluid is applied to the surface of the substrate 201 from a fluid source as the cylindrical rollers 228 are rotated. Alternatively, the method 300 may exclude operation 304, such that the substrate 201 is transferred directly to the first polishing station of the polishing stations 118 before cleaning in the contact cleaning unit 150.

Once the substrate 201 is cleaned in the contact cleaning unit 150, the substrate 201 is transferred to a second polishing station of the polishing stations 118 for additional polishing during operation 312. In optional operation 314, the substrate 201 may undergo a second non-contact cleaning process in a second non-contact cleaning unit after polishing in the second polishing station before being transferred to the cleaning module 108. Contact cleaning the substrate 201, such as by a contact cleaning unit 150 disposed in the pass-through between polishing stations 118, minimizes polishing-station-to-brush-clean transfer time, reducing defects in the substrate.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A system for polishing a substrate, comprising:
one or more polishing stations disposed within a polishing module;
a contact cleaning unit disposed adjacent to the one or more polishing stations; and
a controller configured to:
transfer the substrate to a first polishing station of the one or more polishing stations;
transfer the substrate to the contact cleaning unit from the first polishing station; and
clean the substrate using a contact cleaning method.

2. The system of claim 1, further comprising a non-contact cleaning unit disposed adjacent to a carrier head of the one or more polishing stations, and wherein the controller is further configured to:
before transferring the substrate to the first polishing station, place a substrate on the non-contact cleaning unit; and
before transferring the substrate to the first polishing station but after placing the substrate on the non-contact cleaning unit, clean the substrate using a first non-contact cleaning method.

3. The system of claim 1, wherein the controller is further configured to transfer the substrate to a second polishing station of the one or more polishing stations after cleaning the substrate using the contact cleaning method.

4. The system of claim 3, wherein the controller is further configured to clean the substrate using a second non-contact cleaning method on a second non-contact cleaning unit after polishing the substrate on the second polishing station.

5. The system of claim 1, wherein the contact cleaning unit is a brush cleaner.

6. The system of claim 5, wherein the brush cleaner includes a cylindrical roller configured to contact a surface of the substrate during the contact cleaning method.

7. The system of claim 6, wherein the brush cleaner includes a tubular cover disposed on the cylindrical roller, the tubular cover being a removable sleeve.

8. A system for polishing a substrate, comprising:
one or more polishing stations disposed within a polishing module in a circular arrangement;
a contact cleaning unit disposed adjacent to the one or more polishing stations; and
a controller configured to:
transfer the substrate to a first polishing station of the one or more polishing stations;
transfer the substrate to the contact cleaning unit from the first polishing station; and
clean the substrate using a contact cleaning method.

9. The system of claim 8, further comprising a non-contact cleaning unit disposed adjacent to a carrier head of the one or more polishing stations, and wherein the controller is further configured to:
before transferring the substrate to the first polishing station, place a substrate on the non-contact cleaning unit; and
before transferring the substrate to the first polishing station but after placing the substrate on the non-contact cleaning unit, clean the substrate using a first non-contact cleaning method.

10. The system of claim 8, wherein the controller is further configured to transfer the substrate to a second polishing station of the one or more polishing stations after cleaning the substrate using the contact cleaning method.

11. The system of claim 10, wherein the controller is further configured to clean the substrate using a second non-contact cleaning method on a second non-contact cleaning unit after polishing the substrate on the second polishing station.

12. The system of claim 8, wherein the contact cleaning unit is a brush cleaner.

13. The system of claim 12, wherein the brush cleaner includes a cylindrical roller configured to contact a surface of the substrate during the contact cleaning method.

14. The system of claim 13, wherein the brush cleaner includes a tubular cover disposed on the cylindrical roller, the tubular cover being a removable sleeve.

15. A method for polishing a substrate, comprising:
placing a substrate on a first non-contact cleaning unit
cleaning the substrate using a first non-contact cleaning method;
transferring the substrate to a first polishing station;
transferring the substrate to a contact cleaning unit from the first polishing station; and
cleaning the substrate using a contact cleaning method.

16. The method of claim 15, further comprising transferring the substrate to a second polishing station after cleaning the substrate using the contact cleaning method.

17. The method of claim 16, further comprising cleaning the substrate using a second non-contact cleaning method on a second non-contact cleaning unit after polishing the substrate on the second polishing station.

18. The method of claim 15, wherein the first non-contact cleaning method is spray cleaning.

19. The method of claim 15, wherein the contact cleaning method is brush scrubbing.

20. The method of claim 15, wherein the contact cleaning unit is disposed within a polishing module of a chemical mechanical polishing system.
